(19) United States
(12) Patent Application Publication
(10) Pub. No.: US 2004/0120114 A1
(43) Pub. Date: Jun. 24, 2004

(54) Mounting apparatus for chassis-mounted devices

(76) Inventor: Mark D. Feldmeyer, San Jose, CA (US)

Correspondence Address: HEWLETT-PACKARD COMPANY, Intellectual Property Administration, P.O. Box 272400, Fort Collins, CO, 80527-2400, US

(21) Appl. No.: 10/325,244

(22) Filed: Dec. 18, 2002

(51) Int. Cl. H05K 7/20

(52) U.S. Cl. 361/695

(57) ABSTRACT

Snap features are coupled to a housing that are sized to capture a single flange of the device to be mounted, the single flange being positioned adjacent to a face of the housing. Tensioning features are coupled to the housing and configured to retain the device securely against the snap features.

### BACKGROUND

Devices such as fans, speakers and gauges are often mounted in chassis for various applications. Chassis for various motorized devices contain cooling fans, as do computer cabinets and towers. Chassis also may contain other similarly configured devices, such as speakers or various types of gauges. Conventional mounting techniques for such devices frequently include a housing into which the fan or other device is secured, after which the housing is mounted in the chassis. The devices need to be securely held within the housing and chassis so they do not shake loose or fail due to vibration when being transported.

One conventional mounting technique is illustrated in Prior Art FIG. 1A. Here is depicted a conventional apparatus that features a screw, e.g., a tapping screw, penetrating a flange of a device for securing the device to a housing. In this illustration the device has two parallel flange walls and the screw holds a single flange against a face of the housing.

Prior Art FIG. 1B illustrates a conventional apparatus for securing a device to a housing that features a screw through two parallel flange walls of the device, secured with a nut. Screws, although used universally, are labor intensive and, thus, costly to install. They are frequently difficult to access. Screws need to have mounting holes drilled or molded in the housing. Alignment problems may occur, and screws and nuts can be difficult to retrieve when dropped inside a housing or chassis. In the case of a screw through two flange walls, as shown in FIG. 1B, varying distances between the walls of a given type of device may require stocking a variety of dimensions of screws, driving up manufacturing costs.

Prior Art FIG. 1C illustrates a conventional apparatus for securing a device to a housing that features a plastic alligator-type clip pressed through a hole in a flange of the device. While plastic alligator clips may achieve the goal of securing a device to a housing, they are not reusable. Once installed, plastic alligator clips may be very difficult to remove. In trying to remove such a clip, it is not unusual to have a piece of the clip break off and then there is a problem of retrieving the broken piece or having it loose in the chassis or housing. There is also an alignment issue that may need to be solved since there are two holes, one in the device flange and one in the housing, to be penetrated.

Other conventional approaches include a clip for a fan mount that captures both flange walls of the fan against a spring tension device. While such an apparatus reduces the alignment and dropped parts problems, it will not accommodate a variety of fan thicknesses, so would require a separate mold for each design.

Prior Art FIG. 2A illustrates a conventional fan with two flange walls. Holes are illustrated in the corners for mounting screws or clips as shown in FIGS. 1A, 1B and 1C. Prior Art FIG. 2B illustrates a conventional housing for securing a fan (e.g., fan shown in FIG. 2A), using screws or plastic clips. Such a method of mounting a device is labor intensive and has associated disadvantages mentioned above.

### SUMMARY

A mounting apparatus is disclosed. The mounting apparatus has a housing with a form factor that accommodates a device to be mounted. The housing is configured for being coupled to a chassis. Snap features are coupled to the housing that are sized to capture a single flange of the device to be mounted, the single flange being positioned adjacent to a face of the housing. Tensioning features are coupled to the housing and configured to retain the device securely against the snap features.

### BRIEF DESCRIPTION OF THE DRAWINGS

Prior Art FIG. 1A illustrates a conventional apparatus for securing a device to a housing that features a screw through a flange of the device.

Prior Art FIG. 1B illustrates a conventional apparatus for securing a device to a housing that features a screw through two parallel flanges of the device.

Prior Art FIG. 1C illustrates a conventional apparatus for securing a device to a housing that features a plastic alligator-type clip pressed through a hole in a flange of the device.

Prior Art FIG. 2A illustrates a conventional fan with two flange walls.

Prior Art FIG. 2B illustrates a conventional housing for securing a fan using screws.

FIG. 3A is an illustration of a snap feature and tensioning feature, according to one embodiment.

FIG. 3B is an illustration of a snap feature and tensioning feature having a device installed, in accordance with one embodiment.

FIG. 4A depicts an interior bottom-side view of a housing for mounting a device, in accordance with one embodiment.

FIG. 4B depicts an exterior topside view of a housing for mounting a device, in accordance with one embodiment.

FIG. 5A depicts a housing mounted inside a chassis, according to one embodiment.

FIG. 5B depicts an exterior view of a chassis having a vent for a housing mounted within, according to one embodiment.

FIG. 6 is a flowchart of the steps in a process for mounting a device in a chassis, in accordance with one embodiment.

### DETAILED DESCRIPTION

Reference will now be made in detail to embodiments of the invention, examples of which are illustrated in the accompanying drawings. While the invention will be described in conjunction with the embodiments, it will be understood that they are not intended to limit the invention to these embodiments. On the contrary, the invention is intended to cover alternatives, modifications, and equivalents, which may be included within the spirit and scope of the invention as defined by the appended claims. Furthermore, in the following detailed description, numerous specific details are set forth in order to provide a thorough understanding of the present invention. In other instances, well known methods, procedures, and components have not been described in detail so as not to unnecessarily obscure aspects of the present invention.

Embodiments of the present invention include mounting apparatuses that quickly secure and hold devices in housings, preventing the possible alignment and other problems that may occur with conventional retention devices.

In one embodiment, the mounting apparatus has a housing with a form factor that accommodates a device to be mounted. The housing is configured for being coupled to a chassis. Snap features are coupled to the housing that are sized to capture a single flange of the device to be mounted, the single flange being positioned adjacent to a face of the housing. Tensioning features are coupled to the housing and configured to retain the device securely against the snap features.

Therefore, the assembly time for installing the device is reduced since it requires no installation of screws or clips, and there is no need to maintain an inventory of various-sized hardware to accommodate changing dimensions of the devices to be mounted. Also, the probability of dropping hardware in the housing or chassis is greatly reduced.

In one embodiment, a mounting apparatus such as a snap feature and tensioning feature can be applied to fastening and/or securing fans, gauges, and speakers within a chassis. However, the present embodiment is not limited to use with fans, gauges, and speakers but rather can be applied to a large number of securing applications. It is appreciated that an embodiment of the present invention can be applied to securing other and different kinds of devices to a variety of support structures.

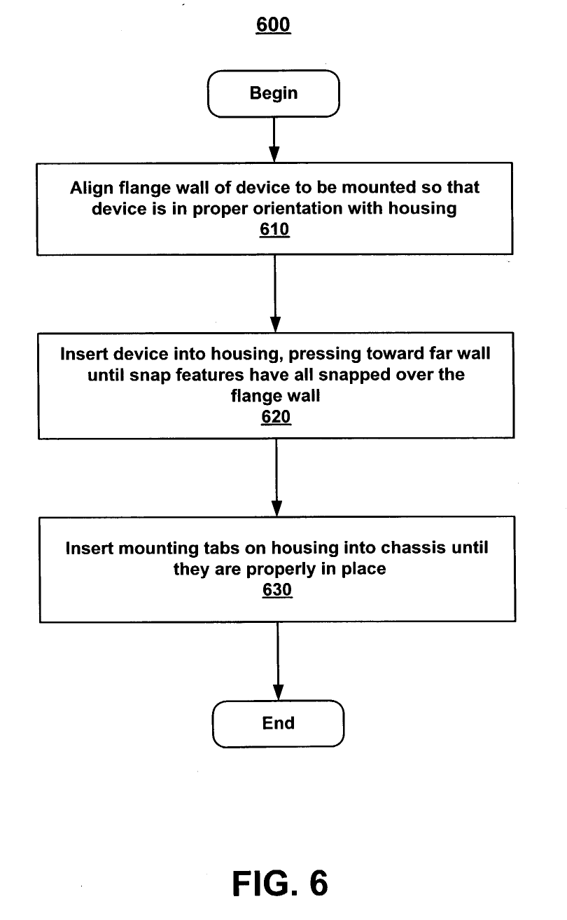

Certain portions of the detailed descriptions of embodiments of the invention, which follow, are presented in terms of processes and methods (e.g., process 600 of FIG. 6). Although specific steps are disclosed herein describing the operations of these processes and methods, such steps are exemplary. That is, embodiments of the present invention are well suited to performing various other steps or variations of the steps recited in the flowchart of the figure herein.

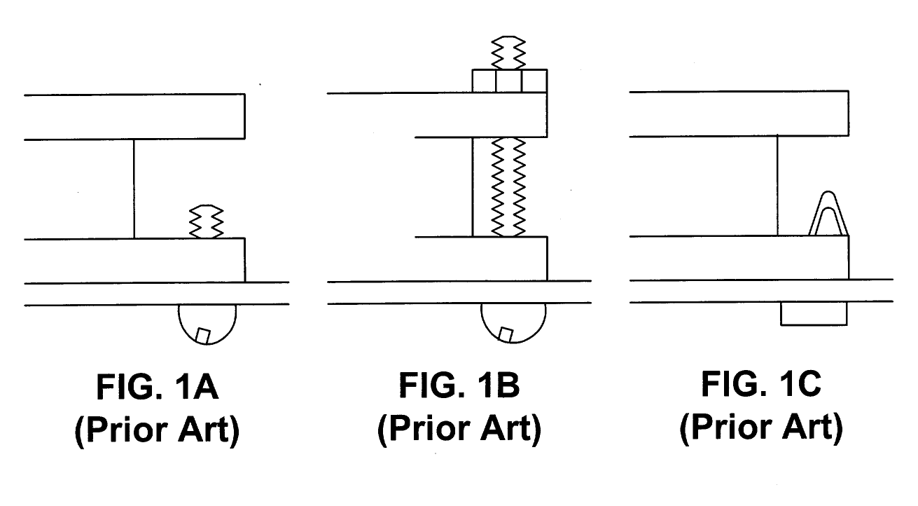

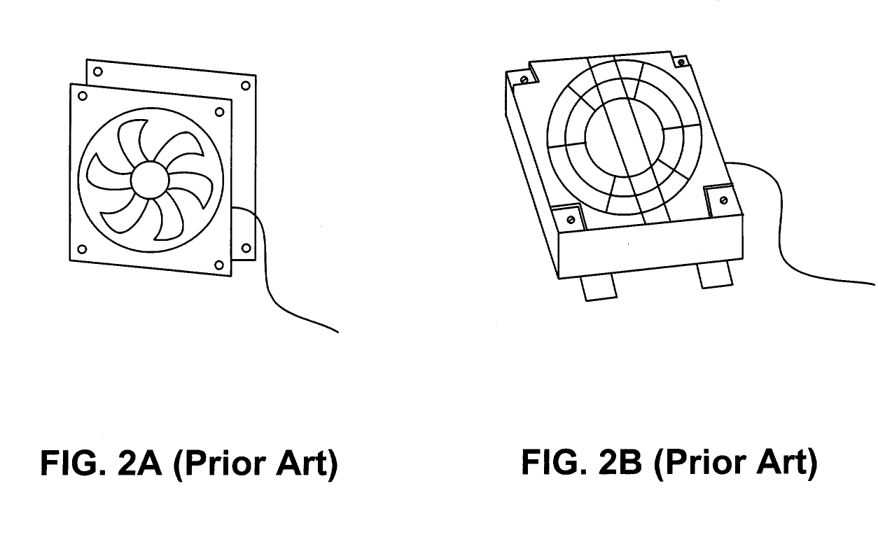

FIG. 3A is an illustration 300 of snap feature 310 and tensioning feature 315, according to one embodiment, with a device having flange walls 330 and 305 poised to be inserted in a direction indicated by arrow 308 into a housing having a side wall 320 and a front wall 327. Snap feature 310 is an elastically deflectable member that may deflect per arrow 316 when flange wall 305 moves past it.

Snap feature 310 and tensioning feature 315 are members molded into a housing 320, according to one embodiment. In another embodiment, snap feature 310 is riveted to housing 320 and tensioning feature 315 is a gasket that is glued onto housing 320. Tensioning feature 315 may alternatively be a coil or leaf spring member. In one embodiment, housing 320 may be molded from a material such as plastic or nylon. In another embodiment, housing 320 may be formed from sheet metal or, in another embodiment, cut and formed from sheet plastic. As device and flange wall 305 move downward in the direction indicated by arrow 308, snap feature 310 moves in the direction of arrow 316, allowing flange wall 305 to move down past the bottom 312 of snap feature 310 and against the top 317 of tensioning feature 315, allowing snap feature 310 to capture flange wall 305 as shown in FIG. 3B.

FIG. 3B illustrates flange wall 305 after installation. Arrow 318 indicates the motion of snap feature 310 after flange wall 305 has moved past it into an installed position. Snap feature 310 is configured to secure flange wall 305 having a thickness 307 no greater than maximum thickness 325. Due to manufacturing tolerances and a variety of suppliers, the thickness 307 of flange wall 305 may vary. The minimum thickness 307 for flange wall 305 is the distance between the top 317 of tensioning feature 315 and the bottom 312 of snap feature 310. Snap feature 310 may be displaced toward the wall of housing 320, as shown by arrow 316 of FIG. 3A, to allow flange wall 305 to move past it toward the face of housing 320. Snap feature 310 has a memory for a position that secures flange wall 305, once in place and past snap feature 310, against tensioning feature 315.

Housing sides 320 may be configured to accommodate a device that's to be mounted. Thus, housing sides 320 may have two or more snap features 310 with associated tensioning features 315 mounted on the front wall 327, depending on the configuration of flange wall 305 of the device and of housing 320. In general, the number of sets of snap features 310 and tensioning features 315 may be determined by the geometry of the flange wall being secured. In one embodiment flange wall 305 may be square or rectangular in shape, in which case four sets of snap features 310 and tensioning features 315 may be appropriate. In another embodiment, flange wall 305 may be round, in which case three sets of snap features 310 and tensioning features 315 may be more appropriate.

Still referring to FIG. 3B, snap feature 310 and tensioning device 315 may be a non-conductive plastic or nylon material or any material suitable for snap and tension devices that may be a member of a housing or may be otherwise attached to the housing. In one embodiment, the device to be secured by snap feature 310 and tensioning feature 315 is a fan having two flange walls, 305 and 330. In one embodiment, flange wall 305 that is captured by snap feature 310 is the flange wall that resides closest to the face of housing 320. In another embodiment, flange wall 305 may be that of a speaker having only one flange wall. In another embodiment, flange wall 305 may be the flange wall of a gauge.

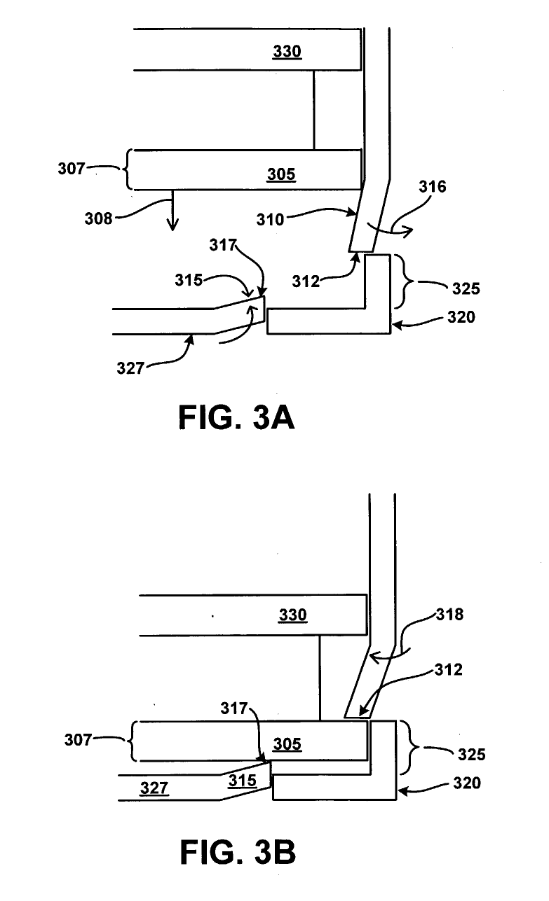

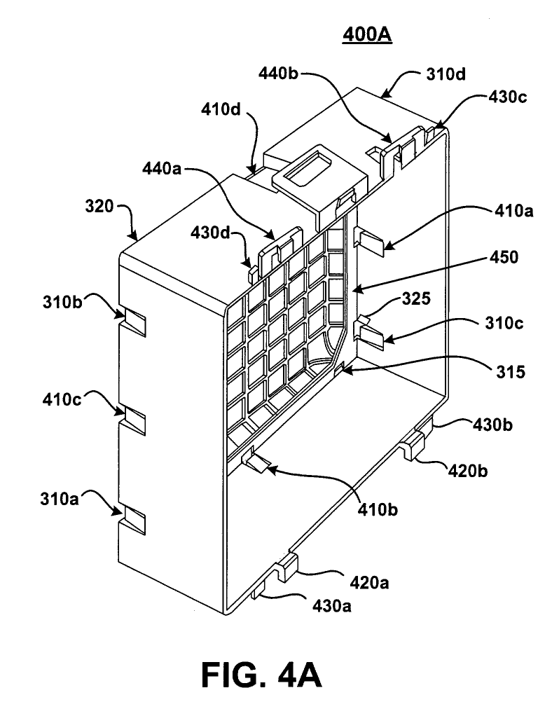

Referring now to FIG. 4A, an interior, bottom-side view 400a of housing 320 is illustrated in accordance with one embodiment of the present invention. Housing 320 is configured for mounting in a chassis such as a computer tower, an operator's panel, a motor housing or any appropriate chassis. In one embodiment, housing 320 has four sides and is configured to accept a device that is square. In other embodiments, housing 320 may be rectangular, round or of any shape that would best accommodate a flange wall of a device to be mounted within housing 320.

Four snap features310a, 310b, 310c and 310d may be molded into housing 320, as illustrated in FIG. 4A, and are located on the sides and near the corners of housing 320, according to one embodiment. According to another embodiment, snap features 310a, 310b, 310c and 310d may be riveted to housing 320. In another embodiment, snap features 310a, 310b, 310c and 310d are glued to housing 320. Four tensioning features 315, three of which are out of sight in FIG. 4A, may be molded into the face if housing 320, near to, but ninety degrees from, associated snap features, according to the present embodiment. Although tensioning features 315 are shown to be molded into housing 320, it should be appreciated that these features may be riveted or glued onto a similar housing to function in a same or similar manner.

Tensioning feature 315, as shown, works in concert with snap feature 310c to hold a flange wall of a device. The flange wall of a device to be secured may be no thicker than maximum thickness 325. Once a flange wall has been aligned with the interior walls of housing 320 and pressed past snap features 310a, 310b, 310c and 310d, toward face 450, snap features 310a, 310b, 310c and 310d will snap back and capture the flange wall and hold it against tensioning features 315. Refer to FIG. 4B for detailed view of one embodiment of all four tensioning features 315a-315d.

Still referring to FIG. 4A, other features of housing 320 include, according to one embodiment, centering features 410a, 410b, 410c and 410d located at the midpoint if each side of housing 320. These centering features 410a, 410b, 410c and 410d similarly to snap features 310a, 310b, 310c and 310d, but have no clearance for the flange wall and no opposing tensioning features such as tensioning feature 315. Centering features 410a, 410b, 410c and 410d function to center a flange wall in housing 320 by exerting tension on the center of each side of a flange wall (e.g., flange wall 305 of FIG. 3A). Tabs 420a, 420b, 440a and 440b are designed to fit into openings in a chassis wall, according to one embodiment, and tabs 430a, 430b, 430c and 430d are spring members that function to hold tabs 420a, 420b, 440a and 440b securely in place.

FIG. 4B depicts an exterior topside view 400b of housing 320 for mounting a device, in accordance with one embodiment of the present invention. Snap features 310a, and 310b are seen in this embodiment from the backside, as viewed from the left of exterior of housing 320. Depressions where snap features 310c and 310d reside are seen at the right side. Centering spring members 410a, 410b, 410c and 410d may also be viewed in accordance with the present embodiment. Tensioning features 315a, 315b, 315c and 315d may be clearly viewed in this embodiment.

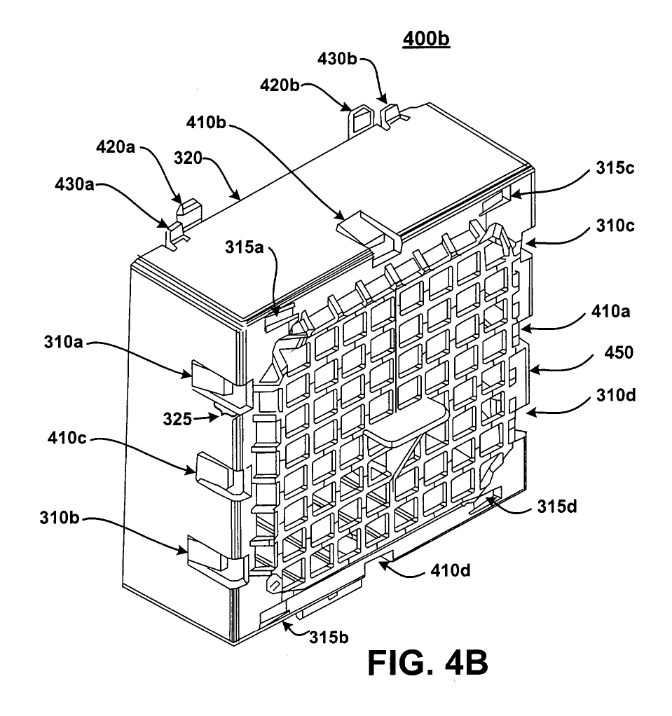

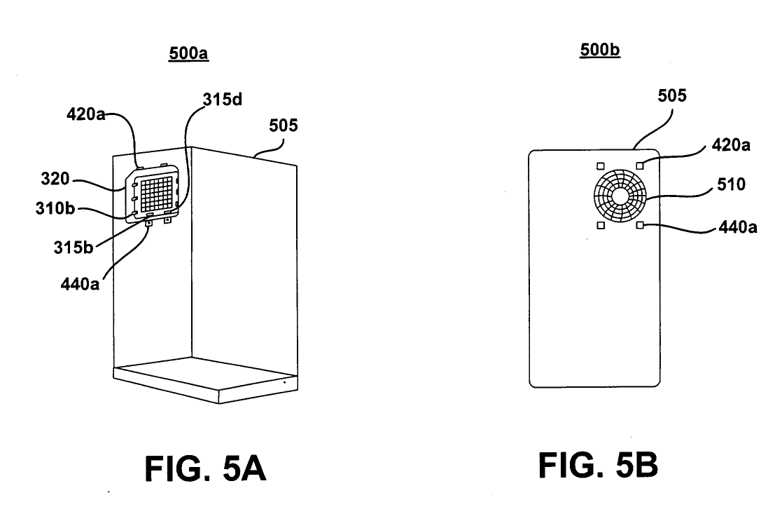

FIG. 5A depicts a cutaway view 500a of a housing 320 mounted inside a chassis 505, according to one embodiment of the present invention. Tensioning features 315b and 315d are shown on the bottom face of housing 320, and snap feature 310b that works in concert with tensioning feature 315b to secure a flange wall of a device within housing 320 may be seen to the left and above tensioning feature 315b. Mounting tabs 420a and 440a for mounting housing 320 on chassis 505 are shown.

FIG. 5B depicts an exterior view 500b of chassis 505 having a vent 510 for a housing (e.g. housing 320) mounted within, according to one embodiment of the present invention. Mounting tabs 420a and 440a are shown, securing a housing (e.g., housing 320 of FIG. 5A) to chassis 500b.

FIG. 6 is a flowchart of the steps in a process 600 for mounting a device in a chassis, in accordance with one embodiment of the present invention. Process 600 begins with step 610 in which a flange wall of a device to be mounted is aligned with a housing (e.g., housing 320 of FIG. 4A). The alignment may assure that the device will be in the proper orientation when installed in the housing and mounted on a chassis, according to one embodiment. In another embodiment the housing may also be the chassis.

At step 620 of flowchart 600, the device to be mounted, such as a fan, is inserted into the housing and pressed toward the inside of the face (e.g., face 450 of FIG. 4A) of the housing. Once the flange wall (e.g., flange wall 305 of FIG. 3) of the device passes all the snap features (e.g., snap features 310a-310d of FIG. 4A) within the housing and the snap features have snapped over and captured the flange wall between the tensioning features (e.g., 315 of FIG. 4A), the device becomes securely mounted in the housing.

At step 630, mounting tabs on the housing (e.g., 420a,420b, 440a and 440b of FIG. 4A) are inserted into openings in a chassis, in accordance with one embodiment, and process 600 is complete. It should be understood that in one embodiment the housing itself may function as a chassis, in which case step 630 may be omitted and process 600 would be complete at the end of step 620.

In summary, a mounting apparatus is disclosed. In one embodiment it has a housing with a form factor that accommodates a device to be mounted. The housing is configured for being coupled to a chassis. Snap features are coupled to the housing that are sized to capture a single flange of the device to be mounted, the single flange being positioned adjacent to a face of the housing. Tensioning features are coupled to the housing and configured to retain the device securely against the snap features.

An embodiment of the present invention, a mounting apparatus for chassis-mounted devices, is thus described. While the present invention has been described in particular embodiments, it should be appreciated that the present invention should not be construed as limited by such embodiments, but rather construed according to the following claims and their equivalents.

What is claimed is:

1. A mounting apparatus comprising:
a housing having a form factor to accommodate a device to be mounted, said housing configurable for coupling to a chassis;
a plurality of snap features coupled to said housing, said plurality of snap features sized to capture a single flange of said device to be mounted; and
a plurality of tensioning features coupled to said housing and configured to retain said device securely against said plurality of snap features.

2. The mounting apparatus as recited in claim 1, wherein said device to be mounted is a fan.

3. The mounting apparatus as recited in claim 1, wherein said device to be mounted is a speaker.

4. The mounting apparatus as recited in claim 1, wherein said plurality of snap features is a plurality of members of said housing.

5. The mounting apparatus as recited in claim 1, wherein said plurality of tensioning features is a plurality of members of said housing.

6. The mounting apparatus as recited in claim 1, wherein said tensioning feature is a gasket.

7. The mounting apparatus as recited in claim 1, wherein said plurality is four.

8. The mounting apparatus as recited in claim 1, wherein said housing comprises additional snap features for centering said device in said housing.

9. The mounting apparatus as recited in claim 1, wherein each of said plurality of snap features is located near one of a plurality of corners of said apparatus.

10. The mounting apparatus as recited in claim 9, wherein each of said plurality of tensioning features is located in the proximity of one of said plurality of snap features.

11. An apparatus for securing a device in a housing comprising:
a plurality of snap features coupled to said housing, said plurality of snap features sized to capture a single flange of said device to be mounted; and
a plurality of tensioning features coupled to said housing and configured to retain said device securely against said plurality of snap features.

12. The apparatus as recited in claim 11, wherein said device to be secured is a fan.

13. The apparatus as recited in claim 11, wherein said housing is configurable for mounting in a chassis.

14. The apparatus as recited in claim 11, wherein said plurality of snap features is a plurality of members of said housing.

15. The apparatus as recited in claim 11, wherein said plurality of tensioning features is a plurality of members of said housing.

16. The apparatus as recited in claim 11, wherein said tensioning feature is a foam gasket.

17. The apparatus as recited in claim 11, wherein said housing comprises additional snap features for centering said device in said housing.

18. The apparatus as recited in claim 11, wherein each of said plurality of snap features is located near one of a plurality of corners of said apparatus.

19. The apparatus as recited in claim 18, wherein each of said plurality of tensioning features is located in the proximity of one of said plurality of snap features.

20. The apparatus as recited in claim 11 wherein said housing is round.

21. A method of retaining a device in a housing, said housing comprising a plurality of snap features sized to capture a single flange wall of said device and a plurality of tensioning features, comprising:
aligning said flange wall of said device to fit within side walls of said housing; and
pressing said flange wall of said device toward a face of said housing, against said plurality of tensioning features, until said plurality of snap features have each snapped over said flange wall.

22. The method as recited in claim 21, wherein said device to be retained is a fan.

23. The method as recited in claim 21, wherein said housing is configurable for mounting in a chassis.

24. The method as recited in claim 21, wherein said plurality of snap features is a plurality of members of said housing.

25. The method as recited in claim 21, wherein said plurality of tensioning features is a plurality of members of said housing.

26. The method as recited in claim 21, wherein each of said plurality of snap features is located near one of a plurality of corners of said apparatus.

27. The method as recited in claim 26, wherein each of said plurality of tensioning features is located in the proximity of one of said plurality of snap features.
